(19) United States
(12) Patent Application Publication
(10) Pub. No.: US 2026/0371607 A1
(43) Pub. Date: Nov. 19, 2026

(54) ELEMENT AND ELEMENT MANUFACTURING METHOD

(71) Applicant: TOPOLOGIC INC, Tokyo (JP)

(72) Inventor: Hiroyuki OHMORI, Tokyo (JP)

(21) Appl. No.: 19/158,771

(22) PCT Filed: Mar. 1, 2024
(86) PCT No.: PCT/JP2024/007789

§ 371 Date: Aug. 21, 2025

(30) Foreign Application Priority Data
Mar. 1, 2023 (JP) 2023-031200

(51) Int. Cl. H10B 61/00; H10N 50/01; H10N 50/10; H10N 50/85

(52) U.S. Cl. CPC H10B 61/20; H10N 50/01; H10N 50/10; H10N 50/85

(57) ABSTRACT

An element is provided comprising a storage layer, an insulating layer, and a fixed layer, each of the storage layer and fixed layer having spontaneous magnetization. The insulating layer is disposed between the storage and fixed layers to form a tunnel magnetic junction. The magnetization direction of the fixed layer is fixed regardless of data written, while that of the storage layer is reversible based on the data. At least one of the storage or fixed layers is an anomalous Hall layer composed of an antiferromagnet exhibiting an anomalous Hall effect. The anomalous Hall coefficient sign of the antiferromagnet is reversible with the written data. At least part of the anomalous Hall layer contains a contaminating element selected from H, B, C, and N.

### CROSS REFERENCE TO RELATED APPLICATIONS

This application is a 371 U.S. National Phase of International Application No. PCT/JP2024/007789, filed on Mar. 1, 2024, which claims priority to Japanese Patent Application No. 2023-031200, filed on Mar. 1, 2023. The entire disclosures of the above applications are incorporated herein by reference.

### BACKGROUND

### Technical Field

The present invention relates to a device and a device manufacturing method.

### Related Art

International Publication No. 2010/067520 (PTL 1) discloses a technology related to a magneto resistive device including a magnesium oxide passivation layer, and to a high-speed, ultra-low-power, non-volatile memory using the same. The memory includes a tunnel magnetoresistance (TMR) film, which is composed of a ferromagnetic free layer, an insulating layer, and a ferromagnetic pinned layer, and an MgO passivation layer on the sidewalls of a protective layer and an orientation control layer. This suppresses element diffusion from each layer of a tunnel magnetoresistance (TMR) device during heat treatment at 350 °C or higher, thereby realizing a magnetic memory cell and a magnetic random access memory (MRAM) having stable high-output read characteristics and low-current write characteristics. Furthermore, when CoFeB is used for the ferromagnetic layer and

MgO is used for the insulating layer, the MgO passivation layer has a (001) orientation.

However, there is still room for improvement in such devices utilizing the tunnel magnetoresistance effect.

### SUMMARY

According to one aspect of the present invention, a device is provided. The device includes a storage layer, an insulating layer, and a pinned layer. Each of the storage layer and the pinned layer is configured to have spontaneous magnetization. The insulating layer is disposed between the storage layer and the pinned layer, thereby forming a tunnel magnetic junction between the storage layer and the pinned layer. A magnetization direction of the pinned layer is configured to be fixed regardless of data written to the device. A magnetization direction of the storage layer is configured to be reversible depending on the data written to the device. At least one of the storage layer or the pinned layer is an anomalous Hall layer composed of an antiferromagnetic material that exhibits an anomalous Hall effect. A sign of an anomalous Hall coefficient of the antiferromagnetic material is configured to be reversible depending on the data written to the device. At least a portion of the anomalous Hall layer is configured to include at least one dopant element selected from the group consisting of H, B, C, and N.

According to the configuration as such, a novel memory device can be provided.

### BRIEF DESCRIPTION OF THE DRAWINGS

FIG. 1 is a front view illustrating an example of the structure of a memory device 10 according to an embodiment.

FIG. 2 is a diagram illustrating an example of the M-H curves of samples according to Experimental Examples 1 to 4.

FIG. 3 is a diagram illustrating the relationship between the MR ratio and external magnetic field for the sample according to Experimental Example 1.

FIG. 4 is a diagram illustrating an example of the relationship between the composition ratio x/y of Mn to Sn in MnₓSn_{y}A_{z} and the MR ratio for each type of dopant element A.

### DETAILED DESCRIPTION

Hereinafter, a preferred embodiment of the present disclosure will be described in detail with reference to the accompanying drawings. In this specification and the drawings, components having substantially the same functional configuration are denoted by the same reference numerals, and duplicate explanations thereof are omitted.

By the way, a program for implementing software described in the present embodiment may be provided on a non-transitory computer-readable recording medium, or it may be made available for download from an external server. Alternatively, it may be provided in a manner that allows the program to be run on an external computer, thereby implementing its functions on a client terminal (i.e., cloud computing).

In the present embodiment, the term “unit” may also include, for example, a combination of hardware resources implemented by a circuit in a broad sense, as well as the information processing performed by software that may be specifically implemented by such hardware resources. Additionally, various types of information are handled in the present embodiment, and such information may be represented by physical values such as signal values indicating voltage or current, by high and low signal levels in a binary bit set consisting of 0s and 1s, or by quantum superposition (i.e., quantum bits), and communication and computation may be executed by a circuit in a broad sense.

Furthermore, the term “circuit” in a broad sense refers to a circuit that is implemented by appropriately combining at least a circuit, circuitry, processor, and memory. That is, it includes application-specific integrated circuits (ASICs), programmable logic devices (such as simple programmable logic devices (SPLDs), complex programmable logic devices (CPLDs) and field-programmable gate arrays (FPGAs)), and the like.

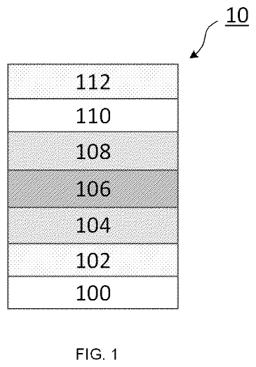

FIG. 1 is a front view illustrating an example of the structure of a memory device 10 according to the present embodiment. The memory device 10 illustrated in FIG. 1 is an example of a device, and includes a substrate 100, an electrode 102, a pinned layer 104, a barrier layer 106 as an insulating layer, a free layer 108 as a storage layer, an intermediate layer 110, and an upper layer 112. The memory device 10 according to the present embodiment is a so-called MTJ (Magnetic Tunnel Junction) device, which reads data as “1” or “0” based on the difference in tunnel magnetoresistance between the parallel and antiparallel spin states, utilizing the tunnel magnetoresistance effect. A memory including the memory device 10 can be used, for example, as an MTJ device in MRAM (Magnetoresistive Random Access Memory), the magnetic head of an HDD (Hard Disk Drive), or in racetrack memory.

The memory device 10 is expected to be used, for example, in STT (Spin Transfer Torque)-MRAM or SOT (Spin Orbit Torque)-MRAM, but may also be used in conventional vertical MRAM. Note that the relative vertical positional relationship between the pinned layer 104 and the free layer 108 in the memory device 10 may be reversed.

The substrate 100 is a substrate made of any material used for memory applications, such as Si. The substrate 100 as such may be provided with electrodes made of W or the like.

The electrode 102 is a layer made of a metal such as Ti or Ta, for example. The material is not particularly limited. The electrode 102 is deposited, for example, on the substrate 100.

The pinned layer 104 is a layer composed of a ferromagnetic or antiferromagnetic material. When the pinned layer 104 is composed of a ferromagnetic material, the ferromagnetic material may be one that is used in ferromagnetic MTJ devices, such as CoFeB or CoFe.

The pinned layer 104 in the present embodiment is configured to have spontaneous magnetization. An antiferromagnetic material with spontaneous magnetization refers to a material that exhibits antiferromagnetic magnetic ordering, such as a canted antiferromagnetic material or a ferrimagnetic material.

The magnetization direction of the pinned layer 104 is configured to be fixed regardless of data written to the memory device 10 as the device. When the pinned layer 104 is composed of an antiferromagnetic material, the antiferromagnetic material in the present embodiment is, for example, an antiferromagnetic material that exhibits the anomalous Hall effect. The antiferromagnetic material as such is, for example, an antiferromagnet in which the anomalous Hall effect is observed in the absence of a magnetic field. The antiferromagnetic material as such is, for example, an antiferromagnet in which the anomalous Hall effect is observed at temperatures above room temperature. The antiferromagnetic material as such is, for example, an antiferromagnet capable of taking binary states through spin rotation. The antiferromagnetic material as such is, for example, a non-collinear antiferromagnet. The non-collinear antiferromagnet is, for example, an Mn₃X-based alloy such as Mn₃Sn, Mn₃Ge, or Mn₃Ga. The crystal structure of these alloys may be hexagonal. When the material constituting the pinned layer 104 according to the present embodiment is an antiferromagnetic material, it contains at least one light element selected from hydrogen, nitrogen, carbon, and boron, in an amount of 0.1 atomic % or more and 20 atomic % or less. With respect to the composition ratio of the Mn₃X-based alloy, the content (amount of substance) of Mn relative to the content (amount of substance) of Sn, Ge, or Ga (including those containing two or more of these elements) is specifically, for example, 2, 2.5, 3, 3.5, 4, 4.5, 5, 5.5, 6, 6.5, 7, 7.5, or 8 times, and may also be within the range between any two of the exemplified values. For example, the content (amount of substance) of Mn relative to the content (amount of substance) of Sn, Ge, or Ga (including those containing two or more of these elements) may be 2 times or more and 6 times or less, preferably 2.3 times or more and 5.5 times or less, and more preferably 2.5 times or more and 5 times or less. The pinned layer 104 is, for example, deposited on the substrate 100. In the present embodiment, the pinned layer 104 is deposited on the substrate 100 via the electrode 102.

The barrier layer 106 is a nonmagnetic insulating layer provided to exhibit TMR. The barrier layer 106 is not particularly limited as long as it functions as an insulating layer, such as MgO, AlOₓ, or TiOₓ. The barrier layer 106 is, for example, deposited on top of the pinned layer 104.

The free layer 108 is a layer composed of an antiferromagnetic material. The free layer 108 can also be configured to have spontaneous magnetization, like the pinned layer 104. For example, the antiferromagnetic material according to the present embodiment is, for example, an antiferromagnetic material that exhibits the anomalous Hall effect. The antiferromagnetic material as such is, for example, an antiferromagnet in which the anomalous Hall effect is observed in the absence of a magnetic field. The antiferromagnetic material as such is, for example, an antiferromagnet in which the anomalous Hall effect is observed at temperatures above room temperature. The antiferromagnetic material as such is, for example, an antiferromagnet capable of taking binary states through spin rotation. The antiferromagnetic material as such is, for example, a non-collinear antiferromagnet. The non-collinear antiferromagnet is, for example, an Mn₃X-based alloy such as Mn₃Sn, Mn₃Ge, or Mn₃Ga. In other words, the antiferromagnet may include, as a main component, at least one element selected from Mn, Sn, and Ge. More specifically, the antiferromagnet is composed of Mn₃Sn. These alloys can, for example, allow the spin to be easily rotated through polarization by magnetic octupoles. The crystal structure of these alloys may be hexagonal. When the material constituting the free layer 108 according to the present embodiment is an antiferromagnetic material, it includes at least one light element selected from hydrogen, nitrogen, carbon, and boron in an amount of 0.1 atomic % or more and 20 atomic % or less. With respect to the composition ratio of the Mn₃X-based alloy, the content of Mn relative to the content of Sn, Ge, or Ga (including those containing two or more of these elements) is preferably 2.5 times or more and 5 times or less. The barrier layer 106 as an insulating layer is disposed between the free layer 108 as a storage layer and the pinned layer 104, thereby forming a tunnel magnetic junction (TMJ) between the free layer 108 and the pinned layer 104. In the present embodiment, the free layer 108 may function as an anomalous Hall layer. The anomalous Hall layer is a layer composed of an antiferromagnetic material that exhibits the anomalous Hall effect. Note that the pinned layer 104 may include an anomalous Hall layer. That is, at least one of the free layer 108 or the pinned layer 104 may include an anomalous Hall layer composed of an antiferromagnetic material that exhibits the anomalous Hall effect.

An antiferromagnetic material that exhibits the anomalous Hall effect and has spontaneous magnetization (e.g., canted antiferromagnet) can, for example, have the direction of its spontaneous magnetization reversed through application of an external magnetic field or the like. A change in the direction of spontaneous magnetization indicates a change in the magnetic structure of the antiferromagnetic material. Such a change in the magnetic structure causes a sign reversal of the anomalous Hall coefficient. The sign reversal of the anomalous Hall coefficient indicates a reversal in the direction of the effective magnetic field within the antiferromagnetic material. Thus, the sign of the anomalous Hall coefficient of the antiferromagnetic material is configured to be reversible depending on the data written to the device. Note that the storage layer is not limited to one being composed solely of an anomalous Hall layer. For example, the storage layer may be configured to have an anomalous Hall layer and a ferromagnetic layer. This allows the reversal of the effective magnetic field, accompanying the sign reversal of the anomalous Hall coefficient of the antiferromagnetic material, to be transmitted to the ferromagnetic layer via magnetic coupling between the anomalous Hall layer and the ferromagnetic layer. As a result, the direction of spontaneous magnetization of the ferromagnetic layer can be interlocked with the sign reversal of the anomalous Hall coefficient, thereby enabling faster response of the device to external signals (e.g., external magnetic fields).

The intermediate layer 110 as a metal layer is provided between the free layer 108 and the upper layer 112, and may support perpendicular magnetization of the free layer 108. The material constituting the intermediate layer 110 is preferably a metal including at least one element selected from Ti, Zr, Hf, Ta, Nb, and W. The intermediate layer 110 may be deposited on top of the free layer 108. In other words, the memory device 10 may include a metal layer. The metal layer is configured to interface with at least one of the storage layer (the free layer 108 in the present embodiment) or the pinned layer 104. For example, the metal layer is deposited so as to be in contact with the barrier layer 106. This can improve the bonding of the barrier layer 106 to the pinned layer 104 or the free layer 108. The metal layer may be formed of a material including at least one element belonging to Group 4, Group 5, or Group 6. For example, the metal layer may be formed of at least one element selected from Ti, Zr, Hf, Ta, Nb, and W.

The upper layer 112 is a layer provided above the intermediate layer 110. The upper layer 112 is composed of Ta or TaN, for example, but the material is not particularly limited. The upper layer 112 may be deposited on top of the intermediate layer 110.

At least a portion of the anomalous Hall layer included in the free layer 108 may be configured to include at least one dopant element selected from the group consisting of hydrogen (H), nitrogen (N), carbon (C), and boron (B). For example, by adding at least one light element such as hydrogen (H), nitrogen (N), carbon (C), or boron (B) as a dopant element in an amount of 0.1 atomic % or more and 20 atomic % or less to an Mn₃X-based (X=Sn, Ge, or Ga) antiferromagnetic alloy, the alloy tends to become amorphous immediately after film formation. When a magnetic tunnel junction (MTJ) film is formed using a crystalline insulating layer, the lattice mismatch at the interface between the crystalline insulating layer and the antiferromagnetic layer is alleviated, resulting in an increased tunnel magnetoresistance (TMR) ratio and improved squareness ratio of magnetization. Accordingly, when a magnetic tunnel junction device is integrated into a memory, it is possible to realize a memory device with low read-out errors and reduced variation. From another perspective, when depositing an antiferromagnetic material that exhibits the anomalous Hall effect, the presence of a dopant element facilitates maintaining the anomalous Hall layer in an amorphous state temporarily. This allows for obtaining a desirable state for forming a device that includes the free layer 108 or the pinned layer 104 containing an antiferromagnetic material with higher crystallinity. In particular, the anomalous Hall layer may be configured to include a dopant element at the interface with the insulating layer. According to this configuration, the crystallinity of the anomalous Hall layer can be enhanced while suppressing the degradation of the magnetic properties of the anomalous Hall layer.

An example of a method of manufacturing the memory device 10 according to the present embodiment will now be described.

First, the layers 102, 104, 106, 108, 110, and 112 are sequentially deposited on the substrate 100 by performing sputtering, while switching the atmosphere or the target. At this time, when depositing layers for introducing a dopant element, such as the pinned layer 104 or the free layer 108, the deposition is performed under conditions in which the dopant element is introduced from an element source toward the sputtering target. For example, during the deposition, a gas (e.g., H₂ gas, N₂ gas, etc.) including the dopant element is introduced, or sputtering is performed using a target including the dopant element. More specifically, for example, during the film formation of the pinned layer 104 and/or the free layer 108, when forming an Mn₃X-based film, light elements (as examples of dopant elements, particularly H, B, C, and N) can be introduced into each layer by mixing not only Ar but also hydrogen or nitrogen gas with the sputtering atmosphere gas, or by performing ion implantation or the like. The gas ratio and other parameters can be appropriately adjusted as needed. Sputtering is performed, for example, under ultrahigh vacuum conditions at room temperature. A heat treatment process may be performed after the deposition of all layers. Accordingly, it becomes possible to promote the crystallization of the pinned layer 104 or the free layer 108, which tends to become amorphous due to the inclusion of the above-mentioned dopant element. For example, as the heat treatment process, annealing may be performed at a heating temperature of 350 °C for five hours. The heating temperature and heating time in annealing can be appropriately adjusted as needed according to the film characteristics and film structure. That is, the method of manufacturing the memory device 10 includes the step of depositing the free layer 108, the barrier layer 106 as an insulating layer, and the pinned layer 104 in the presence of an element source configured to release a dopant element, and this step causes the dopant element to be released from the element source at least during the deposition of an anomalous Hall layer. The element source may be included in the atmosphere during deposition, or may be a target capable of releasing plasma-treated elements. Therefore, the above manufacturing method is not limited to one using sputtering; any suitable method may be used, such as chemical vapor transport (CVT) or molecular-beam epitaxy (MBE).

Note that the configuration according to the memory device 10 described above can also be used as a device in a magnetic sensor such as a TMR sensor. That is, the memory device 10 is merely an example of such a device, and other configurations may also be employed.

### EXPERIMENTAL EXAMPLES

Experimental Examples 1 to 4, which further embody the above-described embodiment, will now be described. In each of Experimental Examples 1 to 4, an Si substrate was used as the substrate 100.

### <Fabrication Procedure>

First, the fabrication procedure of the memory device 10 according to each of Experimental Examples 1 to 4 is described.

### Experimental Example 1

In Experimental Example 1, a pre-prepared Si substrate was first placed on the sample stage of the sputtering apparatus. The sample stage is housed within the sample chamber.

Next, the interior of the sample chamber housing the sample stage was evacuated, and Ar gas (purity 99.999%) as an inert gas was introduced. Thereafter, by sputtering using a Ti target, a Ti film was deposited on the Si substrate to a film thickness of 5 nm. The Ti film may function as the electrode 102.

Next, in addition to Ar gas, H₂ gas (purity 99.99%) was introduced into the sample chamber, thereby forming an atmosphere composed of a mixed gas of Ar gas and H₂ gas. The partial pressure ratio of each gas contained in the mixed gas was such that the partial pressure of Ar gas was 95% and the partial pressure of H₂ gas was 5%, based on the total partial pressure ratio of the mixed gas being 100%. Under this mixed gas atmosphere, sputtering was performed using a target composed of an Mn₃Sn alloy, thereby depositing the pinned layer 104 on the Ti film to a film thickness of 10 nm.

Next, the target was changed from the Mn₃Sn alloy to MgO, and an MgO film as a barrier layer was deposited on the pinned layer 104 to a film thickness of 1 nm.

Next, the target was switched back from MgO to an Mn₃Sn alloy, and under the mixed gas atmosphere, further sputtering was performed, thereby further depositing the free layer 108 on the MgO film to a film thickness of 5 nm.

Next, the target was changed to Zr metal, the atmosphere was again replaced with Ar, and sputtering was performed to deposit a Zr film on the free layer 108 to a film thickness of 5 nm.

Next, the target was changed to Ta metal, and sputtering was performed to deposit a Ta film on the Zr film to a film thickness of 5 nm. The Zr film and the Ta film may function as both the intermediate layer 110 and as an electrode. Note that the fabrication of the upper layer is omitted in this experimental example.

Through this procedure, a sample was obtained as the memory device 10 according to Experimental Example 1, in which each of the pinned layer 104 and the free layer 108 was configured as an anomalous Hall layer, each layer including H as a dopant element.

### Experimental Example 2

The fabrication procedure of the memory device 10 according to Experimental Example 2 is described.

In Experimental Example 2, as in Experimental Example 1, a pre-prepared Si substrate was first placed on the sample stage of the sputtering apparatus.

Next, the interior of the sample chamber housing the sample stage was evacuated, and Ar gas as an inert gas was introduced. Thereafter, by sputtering using a Ta target, a Ta film was deposited on the Si substrate to a film thickness of 5 nm. The Ta film may function as the electrode 102.

Next, sputtering was performed using a target composed of a sintered body of an Mn₃Sn alloy and boron (B), thereby depositing the pinned layer 104 on the deposited Ta film to a film thickness of 15 nm.

Next, the target was changed from the aforementioned sintered body of Mn₃Sn alloy and B to MgO, and an MgO film as a barrier layer was deposited on the pinned layer 104 to a film thickness of 1 nm.

Next, sputtering was performed using a target composed of a sintered body of an Mn₃Sn alloy and graphite (C), thereby further depositing the free layer 108 on the MgO film to a film thickness of 5 nm.

Next, the target was changed to W metal, and sputtering was performed to deposit a W film on the free layer 108 to a film thickness of 5 nm.

Next, the target was changed to Ta metal, and sputtering was performed to deposit a Ta film on the W film to a film thickness of 5 nm.

Through this procedure, a sample was obtained as the memory device 10 according to Experimental Example 2, in which each of the pinned layer 104 and the free layer 108 was configured as an anomalous Hall layer, with B included in the pinned layer 104 and C included in the free layer 108 as dopant elements.

### Experimental Example 3

The fabrication procedure of the memory device 10 according to Experimental Example 3 is described.

In Experimental Example 3, as in Experimental Examples 1 and 2, a pre-prepared Si substrate was first placed on the sample stage of the sputtering apparatus.

Next, the interior of the sample chamber housing the sample stage was evacuated, and Ar gas as an inert gas was introduced. Thereafter, by sputtering using a Ta target, a Ta film was deposited on the Si substrate to a film thickness of 5 nm.

Next, sputtering was performed using a target composed of an iron-cobalt-boron alloy (Fe₆₀Co₂₀B₂₀), thereby depositing the pinned layer 104 on the deposited

Ta film to a film thickness of 1.8 nm.

Next, the target was changed from the iron-cobalt-boron alloy to MgO, and an MgO film as a barrier layer was deposited on the pinned layer 104 to a film thickness of 1 nm.

Next, in addition to Ar gas, N₂ gas (purity 99.99%) was further introduced into the sample chamber, thereby forming an atmosphere composed of a mixed gas of Ar gas and N₂ gas. The partial pressure ratio of each gas contained in the mixed gas was such that the partial pressure of Ar gas was 99% and the partial pressure of N₂ gas was 1%, based on the total partial pressure ratio of the mixed gas being 100%. Under this mixed gas atmosphere, sputtering was performed using a target composed of an Mn₃Ge alloy, thereby further depositing the free layer 108 on the MgO film to a film thickness of 5 nm.

Next, the target was changed to Hf metal, and sputtering was performed to deposit an Hf film on the free layer 108 to a film thickness of 2 nm.

Next, the target was changed to tantalum nitride (TaN), and sputtering was performed to deposit a TaN film on the Hf film to a film thickness of 5 nm.

Through this procedure, a sample was obtained as the memory device 10 according to Experimental Example 3, in which the free layer 108 was configured as an anomalous Hall layer, with N included in the free layer 108 as a dopant element.

### Experimental Example 4

In Experimental Example 4, a pre-prepared Si substrate was first placed on the sample stage of the sputtering apparatus. The sample stage is housed within the sample chamber.

Next, the interior of the sample chamber housing the sample stage was evacuated, and then replaced with Ar gas (purity 99.999%) as an inert gas. Thereafter, by sputtering using a Ta target, a Ta film was deposited on the Si substrate to a film thickness of 5 nm. The Ta film may function as the electrode 102.

Next, under the Ar gas atmosphere, sputtering was performed using a target composed of an Mn₃Sn alloy, thereby depositing the pinned layer 104 on the deposited Ta film to a film thickness of 15 nm.

Next, the target was changed from the Mn₃Sn alloy to MgO, and an MgO film as a barrier layer was deposited on the pinned layer 104 to a film thickness of 1 nm.

Next, the target was switched back from MgO to an Mn₃Sn alloy, and, under the Ar gas atmosphere, further sputtering was performed, thereby further depositing the free layer 108 on the MgO film to a film thickness of 10 nm.

Next, the target was changed to Ta metal, and sputtering was performed to deposit a Ta film on the free layer 108 to a film thickness of 5 nm.

Through this procedure, a sample was obtained as the memory device 10 according to Experimental Example 4, in which each of the pinned layer 104 and the free layer 108 was configured as an anomalous Hall layer, and in which no dopant element such as H was included other than as an unavoidable impurity.

### <Composition Analysis>

Next, the composition of the pinned layer 104 and the free layer 108 according to each of Experimental Examples 1 to 3 described above was identified using X-ray photoelectron spectroscopy (XPS) and mass spectrometry (MS). As a result, the following table was obtained.

TABLE 1

| | Composition Ratio of | Composition Ratio of |
|---|---|---|
| | Pinned Layer 104 | Free Layer 108 |
| Experimental Example 1 | Mn₇₀Sn₂₅H₅ | Mn₇₀Sn₂₅H₅ |
| Experimental Example 2 | Mn₆₅Sn₂₀B₁₅ | Mn₇₀Sn₂₀C₁₀ |
| Experimental Example 3 | Fe₆₀Co₂₀B₂₀ | Mn₇₀Ge₂₀N₁₀ |
| Experimental Example 4 | Mn₇₇Sn₂₃ | Mn₇₇Sn₂₃ |

As above, the pinned layer 104 according to Experimental Examples 1 and 2 included H and B as dopant elements, whereas the pinned layer 104 according to Experimental Examples 3 and 4 included no dopant elements. Additionally, the free layer 108 according to Experimental Examples 1 to 3 included H, C, and N as dopant elements, whereas the free layer 108 according to Experimental Example 4 included no dopant elements.

<Regarding M-H curves>

Next, the M-H curves of the samples according to Experimental Examples 1 to 4 described above are described. First, the procedure for measuring the M-H curves is described. The samples according to Experimental Examples 1 to 4 described above were initially subjected to heat treatment by heating at 350 °C for five hours. Each of the heat-treated samples was then fixed inside a nonmagnetic straw. Next, the straw was placed in the sample space of Quantum Design's MPMS3 such that the magnetic field was applied in a direction perpendicular to the surface of the substrate. Thereafter, with the sample temperature held at room temperature (26 °C), the M-H curves were measured in VSM mode under a magnetic field of 1000 Oe.

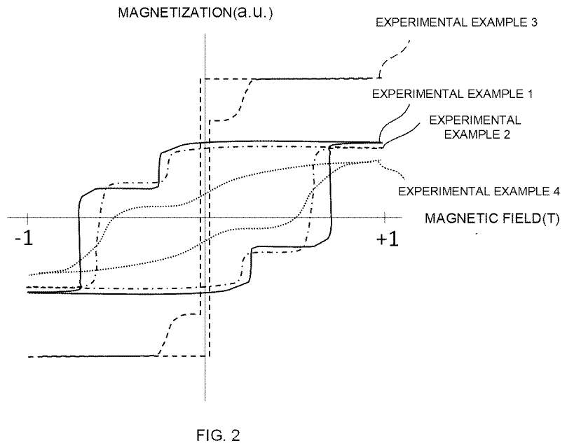

Next, the measured M-H curves are described. FIG. 2 is a diagram illustrating an example of the M-H curves of the samples according to Experimental Examples 1 to 4. As illustrated in FIG. 2, the magnetization of the samples according to Experimental Examples 1 to 4 saturated when an external magnetic field of approximately 1 T was applied. At this point, the saturation magnetization of the samples according to Experimental Examples 1, 2, and 3 was indicated to be greater than the saturation magnetization according to Experimental Example 4. This indicates that magnetic properties are improved by the introduction of dopant elements such as H, B, C, and N into the pinned layer 104 and the free layer 108.

Additionally, the saturation magnetization of the sample according to Experimental Example 3 was particularly higher compared to the saturation magnetization of the samples according to Experimental Examples 1 and 2. This suggests that N is a preferred dopant element. Furthermore, the retention of the sample according to Experimental Example 3 was lower compared to the retention of the samples according to Experimental Examples 1, 2, and 4. This suggests that the sample according to Experimental Example 3 has higher responsiveness to an external magnetic field compared to the other samples.

### <Regarding Magnetoresistance Ratio>

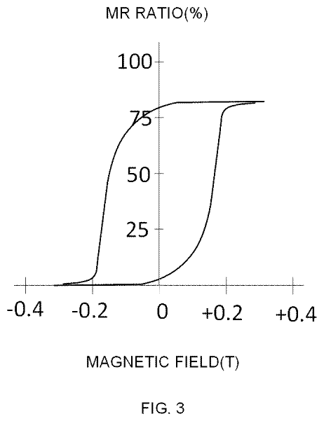

Next, the magnetoresistance ratios (hereinafter referred to as MR ratios) of the samples according to Experimental Examples 1 to 4 described above are described. The table below indicates an example of the MR ratio measurements results. These measurement results were obtained by measuring the magnetoresistance of the samples, used for the above M-H curve measurements, using a current-in-plane tunneling (CIPT) apparatus. FIG. 3 is a diagram illustrating the relationship between the MR ratio and the external magnetic field for the sample according to Experimental Example 1.

TABLE 2

| | MR Ratio |
|---|---|
| Experimental Example 1 | 80% |
| Experimental Example 2 | 55% |
| Experimental Example 3 | 23% |
| Experimental Example 4 | 0.50% |

The above MR ratio measurement results suggest that the introduction of dopant elements such as H, B, C, and N improves the MR ratio.

### <Relationship Between Mn-to-Sn Composition Ratio for Each Dopant Element and Magnetic Properties>

Next, the relationship between MnₓSn_{y}A_{z}, which is an example of an antiferromagnetic material that constitutes an anomalous Hall layer and contains dopant element A, and the MR ratio is described. x represents the amount of substance of Mn per formula unit, y represents the amount of substance of Sn per formula unit, and z represents the amount of substance of dopant element A per formula unit. x/y represents the composition ratio of Mn to Sn. Here, the case where H, B, C, or N is employed as dopant element A is described. When A=H, z/(x+y+z) is approximately 0.01 to 0.02, i.e., z=1 to 2 atomic %. When A=B, C, or N, z/(x+y+z) is approximately 0.08 to 0.12, i.e., z=8 to 12 atomic %.

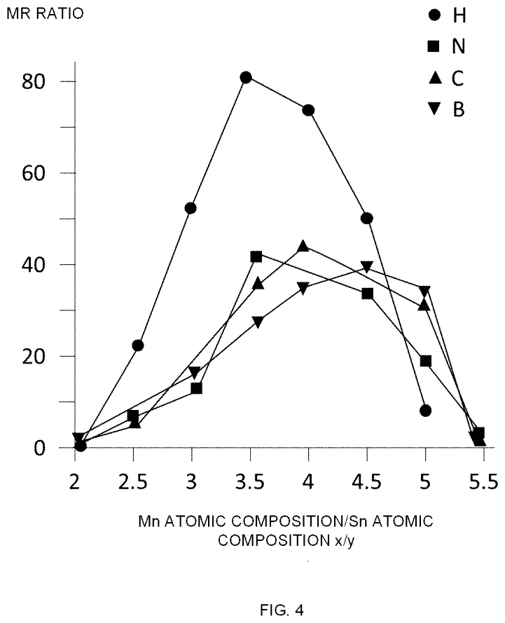

FIG. 4 is a diagram illustrating an example of the relationship between the Mn-to-Sn composition ratio x/y and the MR ratio in MnₓSn_{y}A_{z} for each type of dopant element A. As illustrated in FIG. 4, it is inferred that, regardless of dopant element A, the MR ratio tends to reach its maximum when x/y is roughly between 3 and 5. Additionally, when H is employed as dopant element A, it is inferred that the MR ratio is higher than when other elements are used.

According to the above experimental results, a high MR was obtained when the free layer 108 (at least) contained a light element in an amount of 0.1 atomic % or more and 20 atomic % or less. It was also indicated that an even higher MR can be obtained by setting the elemental ratio of Mn to X within a specified range.

The above-described embodiment may be provided in each of the following modes.
(1) A device comprising: a storage layer; an insulating layer; and a pinned layer, wherein each of the storage layer and the pinned layer is configured to have spontaneous magnetization, the insulating layer is disposed between the storage layer and the pinned layer, thereby forming a tunnel magnetic junction between the storage layer and the pinned layer, a magnetization direction of the pinned layer is configured to be fixed regardless of data written to the device, a magnetization direction of the storage layer is configured to be reversible depending on the data written to the device, at least one of the storage layer or the pinned layer is an anomalous Hall layer composed of an antiferromagnetic material that exhibits an anomalous Hall effect, a sign of an anomalous Hall coefficient of the antiferromagnetic material is configured to be reversible depending on the data written to the device, and at least a portion of the anomalous Hall layer is configured to include at least one dopant element selected from the group consisting of H, B, C, and N.

According to this configuration, when depositing an antiferromagnetic material that exhibits the anomalous Hall effect, the presence of a dopant element facilitates temporarily maintaining the anomalous Hall layer in an amorphous state, thereby making it easier to obtain a device with a storage layer or pinned layer containing an antiferromagnetic material with higher crystallinity.
(2) The device according to (1), wherein: the anomalous Hall layer is configured to include the dopant element at an interface with the insulating layer.
(3) The device according to (1), wherein: the antiferromagnetic material includes, as a main component, at least one element selected from Mn, Sn, and Ge.
(4) The device according to (3), wherein: the antiferromagnetic material is composed of Mn₃Sn.
(5) The device according to any one of (1) to (4), further comprising: a metal layer, wherein the metal layer is configured to interface with at least one of the storage layer or the pinned layer, and includes at least one element belonging to Group 4, Group 5, or Group 6.
(6) The device according to (5), wherein: the metal layer is composed of at least one element selected from Ti, Zr, Hf, Ta, Nb, and W.
(7) A method of manufacturing the device according to claim 1, comprising: depositing the storage layer, the insulating layer, and the pinned layer in the presence of an element source configured to release the dopant element, wherein, in the depositing, the dopant element is released from the element source at least during deposition of the anomalous Hall layer.

According to this configuration, when depositing an antiferromagnetic material that exhibits the anomalous Hall effect, the presence of a dopant element facilitates temporarily maintaining the anomalous Hall layer in an amorphous state, thereby making it easier to obtain a device with a storage layer or pinned layer containing an antiferromagnetic material with higher crystallinity.

Of course, the above are not the only possible implementations.

Finally, although various embodiments of the present disclosure have been described, these are presented merely as examples and are not intended to limit the scope of the invention. The novel embodiments may be implemented in various other forms, and various omissions, substitutions, and changes can be made without departing from the gist of the invention. Such embodiments and their modifications are included within the scope and gist of the invention, and also within the scope of the invention as defined in the claims and their equivalents.

1. A device comprising:
a storage layer;
an insulating layer; and
a pinned layer,
wherein each of the storage layer and the pinned layer is configured to have spontaneous magnetization,
the insulating layer is disposed between the storage layer and the pinned layer, thereby forming a tunnel magnetic junction between the storage layer and the pinned layer,
a magnetization direction of the pinned layer is configured to be fixed regardless of data written to the device,
a magnetization direction of the storage layer is configured to be reversible depending on the data written to the device,
at least one of the storage layer or the pinned layer is an anomalous Hall layer composed of an antiferromagnetic material that exhibits an anomalous Hall effect,
a sign of an anomalous Hall coefficient of the antiferromagnetic material is configured to be reversible depending on the data written to the device, and
at least a portion of the anomalous Hall layer is configured to include at least one dopant element selected from the group consisting of H, B, C, and N.

2. The device according to claim 1, wherein:
the anomalous Hall layer is configured to include the dopant element at an interface with the insulating layer.

3. The device according to claim 1, wherein:
the antiferromagnetic material includes, as a main component, at least one element selected from Mn, Sn, and Ge.

4. The device according to claim 3, wherein:
the antiferromagnetic material is composed of Mn₃Sn.

5. The device according to claim 1, further comprising:
a metal layer,
wherein the metal layer is configured to interface with at least one of the storage layer or the pinned layer, and includes at least one element belonging to Group 4, Group 5, or Group 6.

6. The device according to claim 5, wherein:
the metal layer is composed of at least one element selected from Ti, Zr, Hf, Ta, Nb, and W.

7. A method of manufacturing the device according to claim 1, comprising:
depositing the storage layer, the insulating layer, and the pinned layer in the presence of an element source configured to release the dopant element,
wherein, in the depositing, the dopant element is released from the element source at least during deposition of the anomalous Hall layer.
